(19) United States
(12) Patent Application Publication
(10) Pub. No.: US 2026/0047450 A1
(43) Pub. Date: Feb. 12, 2026

(54) SEMICONDUCTOR DEVICE AND METHOD FOR MANUFACTURING SEMICONDUCTOR DEVICE

(71) Applicant: Rohm Co., Ltd., Kyoto-shi (JP)

(72) Inventor: Soichiro TAKAHASHI, Kyoto-shi (JP)

(21) Appl. No.: 19/361,896

(22) Filed: Oct. 17, 2025

Related U.S. Application Data
(63) Continuation of application No. PCT/JP2024/014097, filed on Apr. 5, 2024.

(30) Foreign Application Priority Data
Apr. 25, 2023 (JP) 2023-071660

(51) Int. Cl. H01L 23/498; H01L 21/48; H01L 21/56; H01L 23/00; H01L 23/31; H01L 25/07

(52) U.S. Cl. CPC H01L 23/49861; H01L 21/4842; H01L 21/56; H01L 23/3121; H01L 23/49866; H01L 25/072; H01L 24/40; H01L 2224/40137; H01L 2224/40227

(57) ABSTRACT

A semiconductor device includes a support member, a semiconductor element and a sealing member. The semiconductor element is disposed on a first side in a thickness direction relative to the support member. The sealing member covers a part of the support member and the semiconductor element. The support member has a first surface facing a second side in the thickness direction and exposed from the sealing member. The first surface is formed with a first uneven region. In an example, the first uneven region has an arithmetic mean roughness between 0.2 μm and 13 μm. In an example, the first uneven region includes a plurality of uneven lines in an arc shape.

### TECHNICAL FIELD

The present disclosure relates to semiconductor devices and methods for manufacturing semiconductor devices.

### BACKGROUND ART

Semiconductor devices incorporating semiconductor elements are used, for example, as power modules to constitute inverters. WO 2023/017708 discloses an example of a conventional semiconductor device. The semiconductor device disclosed in WO 2023/017708 comprises a plurality of semiconductor elements, a support substrate, and a sealing resin. The plurality of semiconductor elements or switching elements are mounted on the support substrate. The sealing resin covers the semiconductor elements and a portion of the support substrate. The support substrate includes an insulating layer, a first metal layer, and a second metal layer. The insulating layer is covered by the first metal layer and the second metal layer. The semiconductor elements are mounted on the first metal layer. The second metal layer is exposed from the sealing resin.

### BRIEF DESCRIPTION OF THE DRAWINGS

FIG. 1 is a perspective view showing a semiconductor device according to a first embodiment of the present disclosure.

FIG. 2 is a plan view partially showing the semiconductor device according to the first embodiment of the present disclosure.

FIG. 3 is a bottom view showing the semiconductor device according to the first embodiment of the present disclosure.

FIG. 4 is a cross-sectional view along the IV-IV line in FIG. 2.

FIG. 5 is a cross-sectional view along line V-V in FIG. 2.

FIG. 6 is an enlarged cross-sectional view showing a part of the semiconductor device according to the first embodiment of the present disclosure.

FIG. 7 is a circuit diagram of the semiconductor device according to the first embodiment of the present disclosure.

FIG. 8 is a diagram showing a vehicle of the first embodiment of the present disclosure.

FIG. 9 is a partial sectional view for explaining the vehicle of the first embodiment of the present disclosure.

FIG. 10 is a partial sectional view showing a method of manufacturing the semiconductor device according to the first embodiment of the present disclosure.

FIG. 11 is a partial sectional view showing the method of manufacturing the semiconductor device according to the first embodiment of the present disclosure.

FIG. 12 is a bottom view of a first variation of the semiconductor device according to the first embodiment of the present disclosure.

FIG. 13 is a cross-sectional view along line XIII-XIII in FIG. 12.

FIG. 14 is a partially enlarged cross-sectional view of the first variation of the semiconductor device according to the first embodiment of the present disclosure.

FIG. 15 is a bottom view of a semiconductor device according to a second embodiment of the present disclosure.

FIG. 16 is a sectional view showing a method of manufacturing the semiconductor device according to the second embodiment of the present disclosure.

FIG. 17 is a sectional view showing the method of manufacturing the semiconductor device according to the second embodiment of the present disclosure.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, in the description of the present disclosure, the expression “A face A faces (a first side or a second side) in a direction B” is not limited to the situation where the angle of the face A to the direction B is 90° and includes the situation where the face A is inclined with respect to the direction B.

### First Embodiment

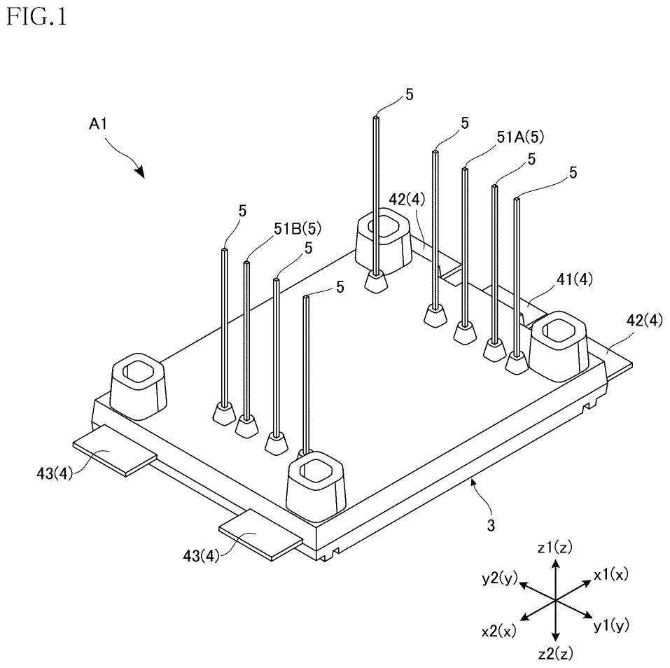

FIGS. 1 to 7 show a semiconductor device according to a first embodiment of the present disclosure. The semiconductor device A1 of the present embodiment comprises a support member 1, a plurality of first semiconductor elements 2A, a plurality of second semiconductor elements 2B, a sealing member 3, a plurality of main current terminals 4, a plurality of control terminals 5, a first conductive member 61, and a second conductive member 62.

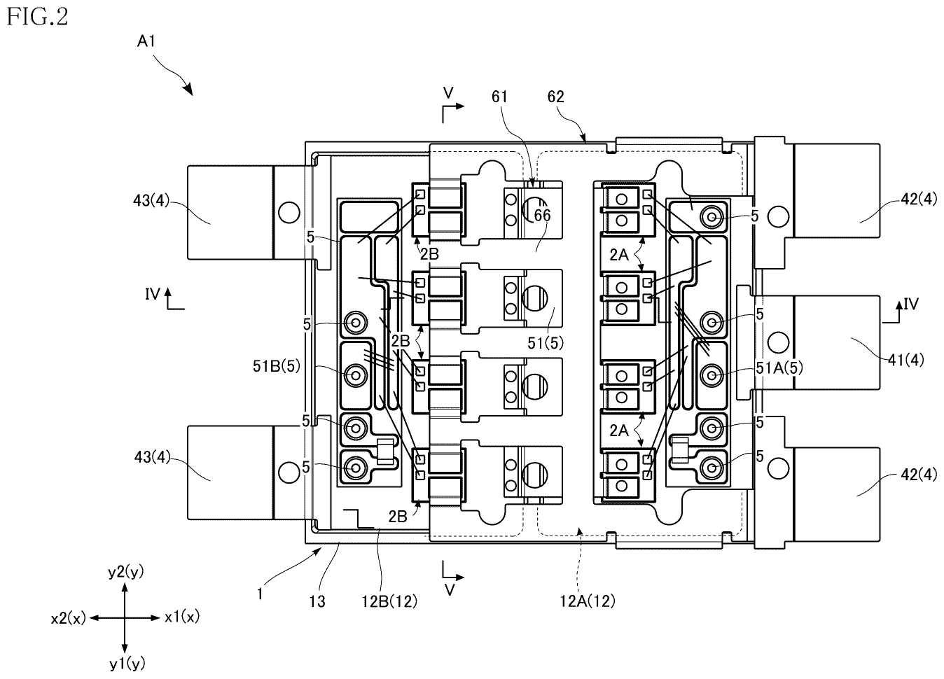

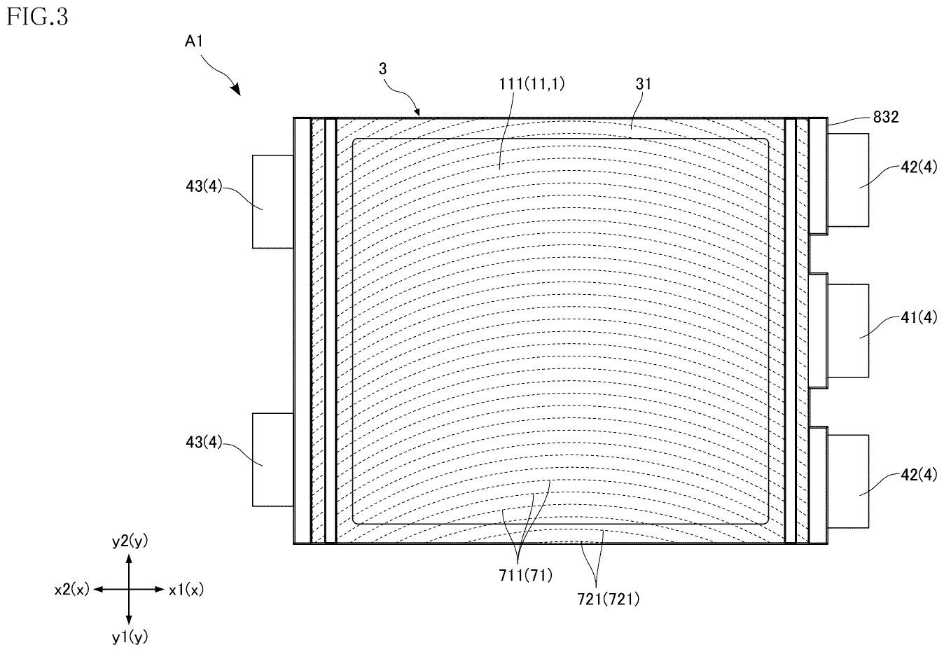

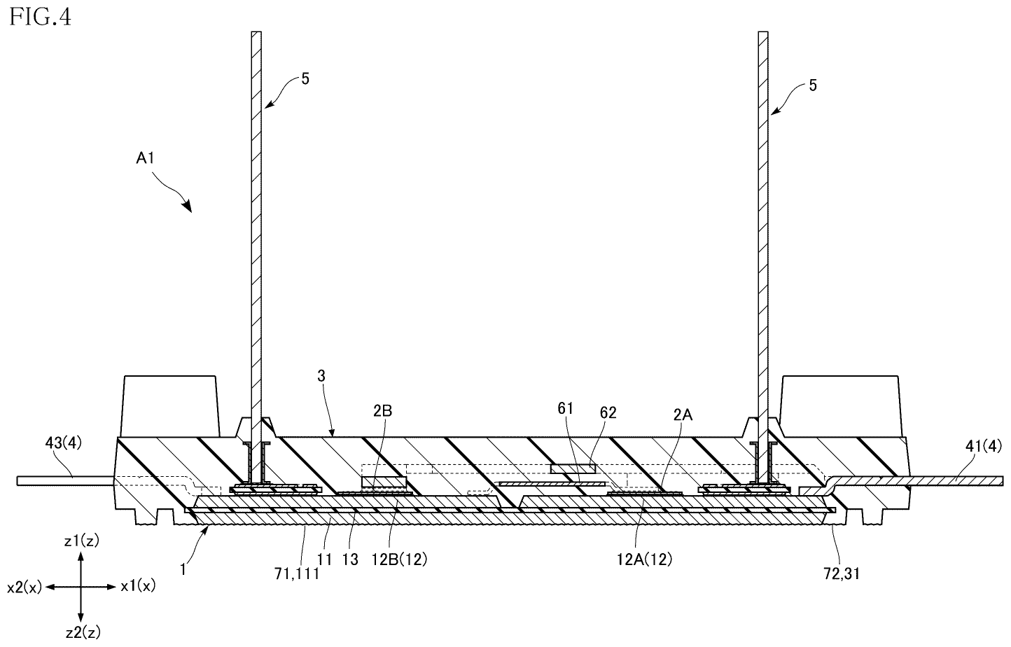

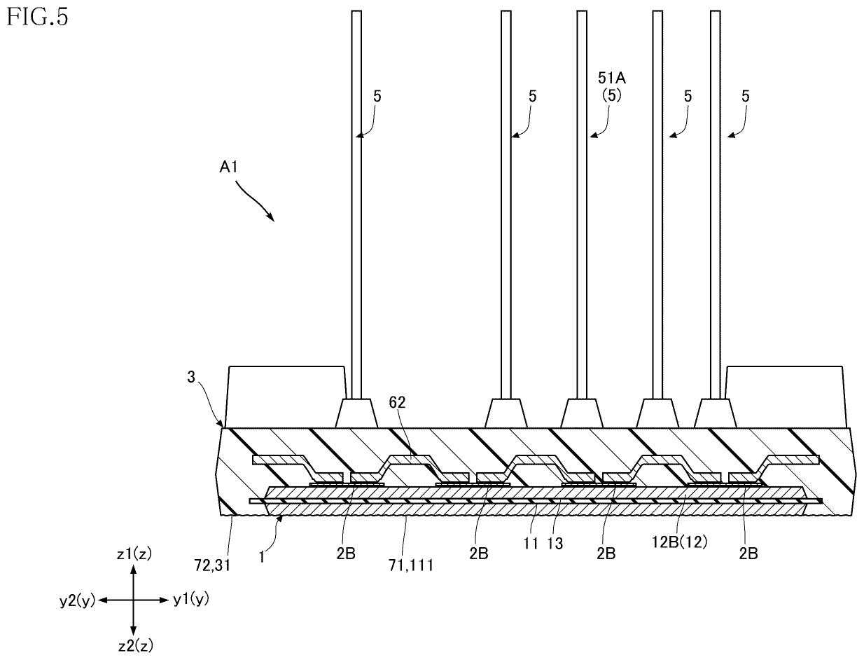

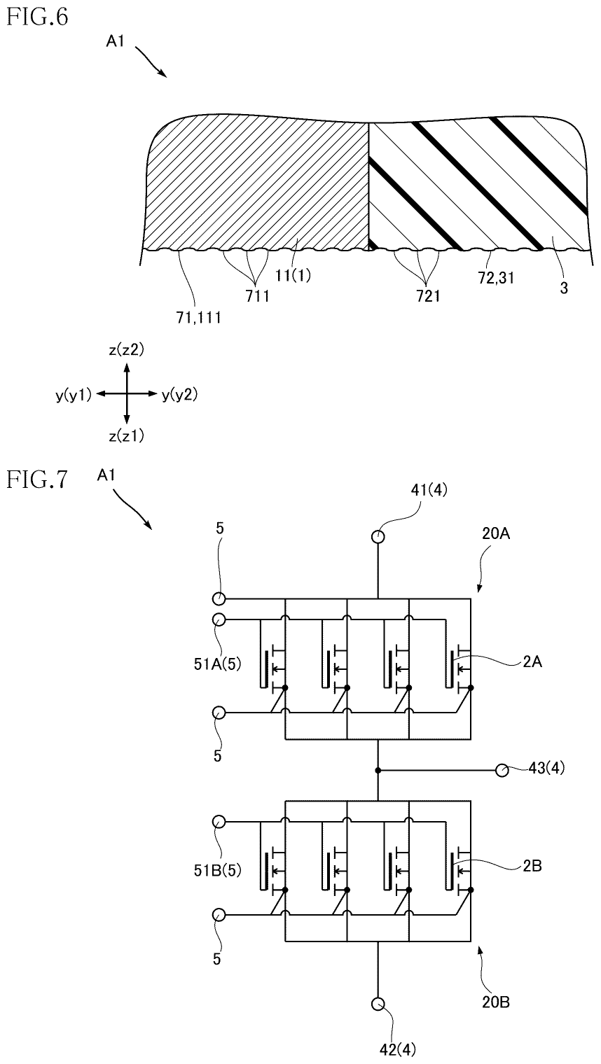

FIG. 1 is a perspective view showing the semiconductor device A1. FIG. 2 is a plan view showing a part of the semiconductor device A1. FIG. 3 is a bottom view showing the semiconductor device A1. FIG. 4 is a cross-sectional view along the IV-IV line in FIG. 2. FIG. 5 is a cross-sectional view along the V-V line in FIG. 2. FIG. 6 is an enlarged cross-sectional view showing a part of the semiconductor device A1. FIG. 7 is a circuit diagram of the semiconductor device A1.

### Support Member 1:

Support member 1 supports first semiconductor elements 2A and second semiconductor elements 2B. The specific configuration of support member 1 is not limited, and in this embodiment, it is configured, for example, by a DBC (Direct Bonded Copper) substrate or an AMB (Active Metal Brazing) substrate. The support member 1 includes an insulating layer 13, a second metal layer 12, and a first metal layer 11. The second metal layer 12 includes a first region 12A and a second region 12B. The dimension of the support member 1 in the thickness direction z is, for example, not less than 0.4 mm and not more than 3.0 mm.

The first metal layer 11 is formed on the lower surface (the surface facing the z2 side in the thickness direction z) of the insulating layer 13. The constituent material of the first metal layer 11 includes, for example, Cu (copper). The first metal layer 11 has a first surface 111. The first surface 111 is a plane facing the z2 side in the thickness direction z. The first surface 111 is exposed from the sealing member 3 as shown in FIGS. 3, 4, and 5. In plan view, the first metal layer 11 overlaps with the first region 12A and the second region 12B.

The first surface 111 of the first metal layer 11 has a first uneven region 71. The first surface 111 may include the first uneven region 71 and other regions, or its entire surface may be the first uneven region 71. In the illustrated example, the first uneven region 71 is provided on the entire region of the first surface 111.

The surface roughness of the first uneven region 71 is not limited. When it is intended to achieve the effect to be described below, the arithmetic mean roughness of the first uneven region 71 may preferably be not less than 0.2 μm and not more than 13 μm.

As shown in FIG. 3, the first uneven region 71 is made up of a number of uneven lines 711. The specific configurations of the uneven lines 711 are not limitative. For example, the configuration of the uneven lines 711 may be determined by the way the first uneven region 71 is made. For example, when the first uneven region 71 is formed by machine cutting, the uneven lines 711 are formed by alternately arranging a plurality of mountain shapes and a plurality of valley shapes as shown in FIG. 6. When the first uneven region 71 is formed by machine cutting using a rotating cutting tool, the uneven lines 711 are each arc-shaped as viewed in the thickness direction z, as shown in FIG. 3.

The insulating layer 13 is composed mainly of a ceramic material with excellent thermal conductivity. Such a ceramic material is, for example, SiN (silicon nitride). The insulating layer 13 is not limited to ceramics, but may be, for example, an insulating resin sheet. The insulating layer 13 is, for example, rectangular in plan view. The dimension of the insulating layer 13 in the thickness direction z is, for example, not less than 0.05 mm and not more than 1.0 mm.

The second metal layer 12 is formed on the z1 side in the z direction of the insulating layer 13. The constituent material of the second metal layer 12 includes, for example, Cu (copper). In addition to or in place of Cu (copper), the constituent material may include, for example, Al (aluminum). The dimension of the second metal layer 12 in the thickness direction z is, for example, not less than 0.1 mm and not more than 1.5 mm.

In this embodiment, the second metal layer 12 includes a first region 12A and a second region 12B. The first region 12A and the second region 12B are spaced apart in the first direction x. The first region 12A is located on the x1 side of the second region 12B in the first direction x. The first region 12A and the second region 12B are, for example, rectangular in plan view. The first region 12A and the second region 12B, together with the first conductive member 61 and the second conductive member 62, constitute a path for the main circuit current to be switched by the first semiconductor elements 2A and the second semiconductor elements 2B.

### First Semiconductor Elements 2A & Second Semiconductor Elements 2B:

The first semiconductor elements 2A and the second semiconductor elements 2B are electronic components to operate as a functional core of the semiconductor device A1. The constituent materials of each first semiconductor element 2A and each second semiconductor element 2B are, for example, semiconductor materials mainly composed of SiC (silicon carbide). Instead of SiC, the semiconductor material may be Si (silicon), GaN (gallium nitride), or C (diamond), for instance. The first semiconductor elements 2A and the second semiconductor elements 2B each may be a power semiconductor chip with a switching function, such as a MOSFET (Metal Oxide Semiconductor Field Effect Transistor).

In this embodiment, each of the first semiconductor elements 2A and the second semiconductor elements 2B is a MOSFET, though the present disclosure is not limited thereto. Other transistors such as IGBTs (Insulated Gate Bipolar Transistors) may also be used. The first semiconductor elements 2A and the second semiconductor elements 2B may be of the same kind. For example, the first semiconductor elements 2A and the second semiconductor elements 2B may be n-channel MOSFETs, or may be p-channel MOSFETs.

The drain electrodes of the first semiconductor elements 2A are electrically connected to the first region 12A. The drain electrodes of the second semiconductor elements 2B are electrically connected to the second region 12B.

### Sealing Member 3:

The sealing member 3 covers the first semiconductor elements 2A, the second semiconductor elements 2B, the support member 1 (excluding the first surface 111), a portion of each of the main current terminals 4, a portion of each of the control terminals 5, the first conductive member 61, and the second conductive member 62. The sealing member 3 in this embodiment is, for example, made of black epoxy resin. The sealing member 3 is, for example, formed by molding. As an example, the sealing member 3 has a dimension in the first direction x of about 35 mm to 60 mm, a dimension in the second direction y of about 35 mm to 50 mm, and a dimension in the thickness direction z of about 4 mm to 15 mm. These dimensions may be the maximum values of the sizes in the respective directions.

The sealing member 3 has a reverse surface 31. The reverse surface 31 is a surface facing the z2 side in the thickness direction z. In this embodiment, the reverse surface 31 has a second uneven region 72. The reverse surface 31 may include the second uneven region 72 and other regions, or the second uneven region 72 may be provided over the entire surface. In the illustrated example, the second uneven region 72 is provided over the entire part of the reverse surface 31.

The surface roughness of the second uneven region 72 is not limitative. When the first uneven region 71 is intended to produce the effect to be described below, the arithmetic mean roughness of the second uneven region 72 may also be not less than 0.2 μm and not more than 13 μm.

As shown in FIG. 3, the second uneven region 72 is made up of a number of uneven lines 721. The specific configurations of the uneven lines 721 are not limitative. For example, the configuration of the uneven lines 721 may be determined by the method of forming the second uneven region 72. For example, when the second uneven region 72 is formed by machine cutting, the uneven lines 721 are formed by alternately arranging a plurality of mountain shapes and a plurality of valley shapes as shown in FIG. 6. When the second uneven region 72 is formed by machine cutting using a rotating cutting tool, the uneven lines 721 are each arc-shaped as viewed in the thickness direction z, as shown in FIG. 3. As an example, when the first uneven region 71 and the second uneven region 72 are collectively formed by using a rotating cutting tool, the uneven lines 711 and the uneven lines 721 may be continuous with each other.

### Main Current Terminals 4:

The main current terminals 4 are terminals through which main current switched by the semiconductor device A1 is inputted or outputted. In this embodiment, the main current terminals 4 include a first power terminal 41, two second power terminals 42, and two output terminals 43. These main current terminals 4 may be made of a metal plate. This metal plate may contain, for example, Cu (copper) or a Cu (copper) alloy.

The first power terminal 41 is located on the x1 side of the first direction x. The first power terminal 41 is electrically connected to the first region 12A. Thus, the first power terminal 41 is electrically connected to the drain electrodes of the first semiconductor elements 2A.

The two second power terminals 42 are disposed on the x1 side of the first direction x and are disposed on both sides of the first power terminal 41 in the second direction y. The two second power terminals 42 are electrically connected to the source electrodes of the second semiconductor elements 2B via the second conductive member 62. The second conductive member 62 is made of, for example, a metal plate. This metal plate may contain, for example, Cu (copper) or a Cu (copper) alloy. The second conductive member 62 may be formed integral with the two second power terminals 42.

The two output terminals 43 are disposed on the x2 side of the first direction x. The two output terminals 43 are electrically connected to the second region 12B. The second region 12B is electrically connected to the source electrodes of the first semiconductor elements 2A via the first conductive member 61. Thus, the two output terminals 43 are electrically connected to the source electrodes of the first semiconductor elements 2A and the drain electrodes of the second semiconductor elements 2B. The first conductive member 61 is made of, for example, a metal plate. This metal plate may contain, for example, Cu (copper) or a Cu (copper) alloy.

### Control Terminals 5:

The control terminals 5 are terminals through which control signals and detection signals for operating the semiconductor device A1 are inputted or outputted. The control terminals 5 protrude from the sealing member 3 in the z1 direction, as shown in FIG. 1.

The control terminals 5 include a first gate terminal 51A and a second gate terminal 51B. The first gate terminal 51A is electrically connected to the gate electrodes of the first semiconductor elements 2A. The second gate terminal 51B is electrically connected to the gate electrodes of the second semiconductor elements 2B. The other control terminals 5 may be used, for example, as a source sense terminal, a temperature monitoring terminal, a current monitoring terminal, or a voltage monitoring terminal.

FIG. 7 shows the circuit diagram of the semiconductor device A1. The semiconductor device A1 is provided with a half-bridge circuit including an upper arm circuit 20A and a lower arm circuit 20B. The upper arm circuit 20A may be composed of the first region 12A and the first semiconductor elements 2A electrically connected to the first region. The first semiconductor elements 2A are connected in parallel between the first power terminal 41 and the output terminals 43. The gate electrodes of the first semiconductor elements 2A in the upper arm circuit 20A are connected in parallel to the first gate terminal 51A. The first gate terminal 51A may be connected to a gate driver or other drive circuit located outside the semiconductor device A1, and when a gate voltage is applied to the first gate terminal 51A, the first semiconductor elements 2A in the upper arm circuit 20A are driven simultaneously.

The lower arm circuit 20B may be composed of the second region 12B and the second semiconductor elements 2B electrically connected to the second region. The second semiconductor elements 2B are connected in parallel between the output terminals 43 and the second power terminals 42. The gate electrodes of the second semiconductor elements 2B in the lower arm circuit 20B are connected in parallel to the second gate terminal 51B. The second gate terminal 51B may be connected to a gate driver or other drive circuit located outside the semiconductor device A1, and when a gate voltage is applied to the second gate terminal 51B, the second semiconductor elements 2B in the lower arm circuit 20B are driven simultaneously.

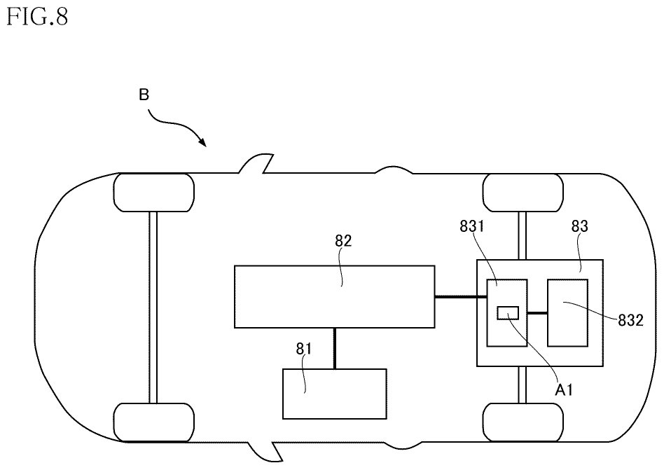

FIG. 8 is a schematic diagram showing a vehicle B equipped with the semiconductor device A1. The vehicle B is, for example, an electric vehicle (EV).

The vehicle B is equipped with an on-board charger 81, a storage battery 82, and a drive train 83. Power is supplied to the on-board charger 81 wirelessly from an outdoor power supply facility (not shown). Alternatively, power may be supplied from the power supply facility to the on-board charger 81 via a wired connection. The on-board charger 81 may be equipped with a step-up DC-DC converter. The voltage of the power supplied to the on-board charger 81 is boosted by the DC-DC converter before being supplied to the storage battery 82. The boosted voltage is, for example, 600 V.

The drive train 83 is used for driving the vehicle B. The drive train 83 includes an inverter 831 and a drive source 832. The semiconductor device A1 constitutes a part of the inverter 831. The electric power stored in the storage battery 82 is supplied to the inverter 831. The electric power supplied from the storage battery 82 to the inverter 831 is direct current. Alternatively, a step-up DC-DC converter may be provided between the storage battery 82 and the inverter 831. The inverter 831 converts DC power into AC power. The inverter 831, including the semiconductor device A1, is electrically connected to the drive source 832. The drive source 832 includes an AC motor and a transmission. When the AC power generated by the inverter 831 is supplied to the drive source 832, the AC motor is driven, and its rotational motion is sent to the transmission. The transmission reduces the rotational speed of the rotational motion as appropriate and rotates the drive shaft of the vehicle B, whereby the vehicle B is driven. In order to drive the vehicle B properly, it is necessary to control the rotational speed of the AC motor based on information such as the amount of operation of the accelerator pedal. In the inverter 831, the semiconductor device A1 is needed to output AC power whose frequency is appropriately adjusted correspondingly to the required rotational speed of the AC motor.

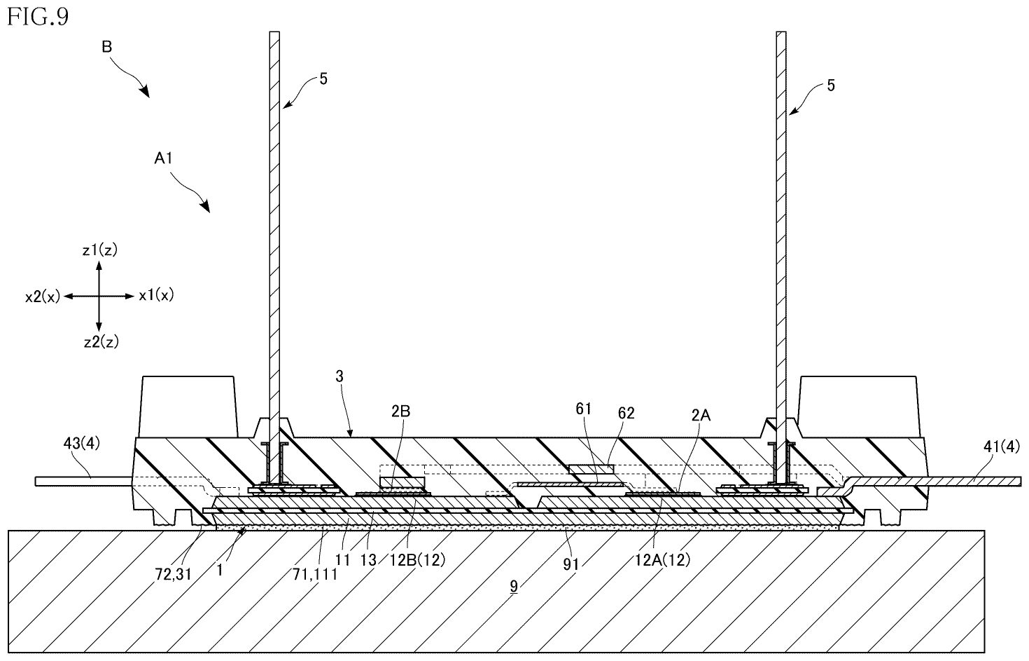

FIG. 9 shows the semiconductor device A1 mounted on the vehicle B. In the illustrated example, the semiconductor device A1 is attached to the cooling system 9 of the vehicle B. The cooling system 9 is formed of materials containing a metal such as Al (aluminum). In an embodiment, a flow passage is formed inside the cooling system 9, and a refrigerant is flowed through the flow passage. The semiconductor device A1 is attached to the cooling system 9 via a heat transfer medium 91. The heat transfer medium 91 may be, for example, thermal grease. The heat transfer medium 91 is held in contact with the first surface 111 of the semiconductor device A1.

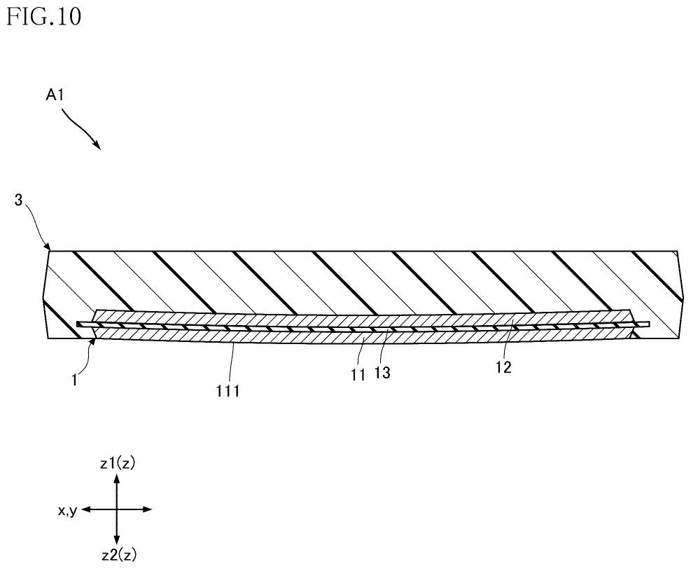

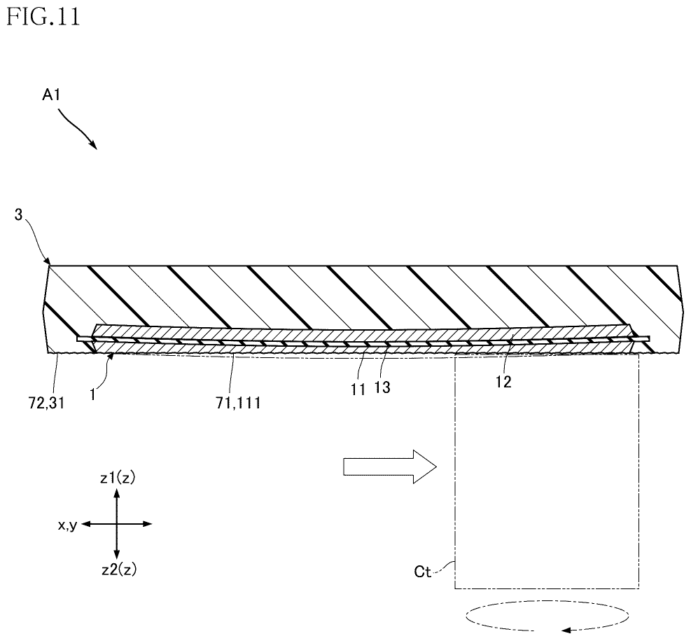

An example of a method for manufacturing the semiconductor device A1 is described below with reference to FIGS. 10 and 11.

FIG. 10 shows a state in the manufacturing method of the semiconductor device A1. Specifically, FIG. 10 shows a state in which the first semiconductor elements 2A, the second semiconductor elements 2B, the first conductive member 61, the second conductive member 62, the main current terminals 4, and the control terminals 5 are mounted on the support member 1, and formation of the sealing member 3 has been completed. For ease of understanding, FIG. 10 shows only the support member 1 and the sealing member 3.

In most cases, when the support member 1 is completed, no significant warping occurs in the support member 1. However, after the first semiconductor elements 2A and the second semiconductor elements 2B are mounted on the support member 1 and the sealing member 3 is completed, warping may occur in the support member 1. According to the inventor's research, the support member 1 tends to bulge toward the z2 side in the thickness direction z, as shown in FIG. 10.

Next, as shown in FIG. 11, a first uneven region 71 is formed. In this embodiment, the first uneven region 71 is formed by machine cutting. A rotating cutting tool Ct may be used for machine cutting. In the illustrated example, the cutting tool Ct rotates around an axis extending in the thickness direction z. The first metal layer 11 of the support member 1 is subjected to cutting by the cutting tool C. This process forms the first uneven region 71 on the first surface 111. In the illustrated example, the first uneven region 71 is formed on the entire first surface 111. Alternatively, depending on the warping state of the support member 1, the first uneven region 71 may be formed only on a part of the first surface 111. The amount of the first metal layer 11 to be cut by machine cutting is not limitative. For example, when the initial size of the first metal layer 11 in the thickness direction z prior to cutting is about 800 μm, the amount of cutting may preferably be 150 μm or more.

In this embodiment, when the first metal layer 11 is processed by machine cutting, the sealing member 3 is also subjected to the cutting. As a result, a second uneven region 72 is formed on the reverse surface 31 of the sealing member 3. According to such machining, the uneven lines 711 of the first uneven region 71 and the uneven lines 721 of the second uneven region 72 are continuous with each other.

Next, advantages of the semiconductor device A1 and the manufacturing method of the semiconductor device A1 will be described below.

When the semiconductor device A1 is mounted on the vehicle B, heat transfer medium 91 is placed between the cooling system 9 and the first surface 111. When the semiconductor device A1 is in use, the first semiconductor elements 2A and the second semiconductor elements 2B may generate heat intermittently. This causes the support member 1 to expand and contract repeatedly. This behavior tends to cause the heat transfer medium 91 to be discharged from between the cooling system 9 and the first surface 111. In light of this, by the present embodiment, the support member 1 has the first uneven region 71, formed on the first surface 111 of the first metal layer 11. The uneven lines 711 of the first uneven region 71 are capable of suppressing the discharge of the heat transfer medium 91 caused by the repeated expansion and contraction of the support member 1. Accordingly, it is possible to prevent insufficient heat dissipation from the semiconductor device A1.

According to the inventor's research, it has been found that when the arithmetic mean roughness of the first uneven region 71 is not less than 0.2 μm and not more than 13 μm, the discharge of the heat transfer medium 91 can be effectively suppressed even when the expansion and contraction of the support member 1 are repeated 1,000 times or more.

By setting the cutting amount for forming the first uneven region 71 to be not less than 150 μm, the thickness of the first metal layer 11 can be advantageously reduced, which contributes to enabling more heat dissipation.

In the illustrated example, the first uneven region 71 is provided on the entirety of the first surface 111. This allows all the area of the first surface 111 to contribute to suppressing the discharge of the heat transfer medium 91.

By forming the first uneven region 71 by machining, the uneven lines 711 may each have steep or sharp shapes. Such shapes are capable of suppressing the discharge of the heat transfer medium 91 more reliably.

A second uneven region 72 is formed on the reverse surface 31 of the sealing member 3. This contributes to suppressing the discharge of the heat transfer medium 91 from between the second uneven region 72 and the cooling system 9. Thus, the second uneven region 72 is advantageous to collaborating with the first uneven region 71 in suppressing the discharge of the heat transfer medium 91 from between the first uneven region 71 and the cooling system 9.

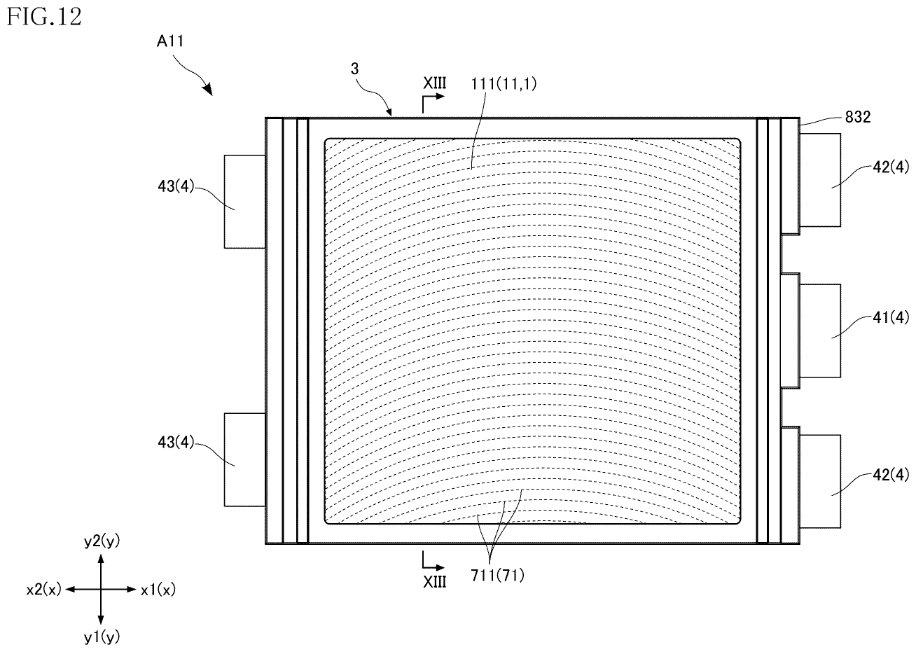

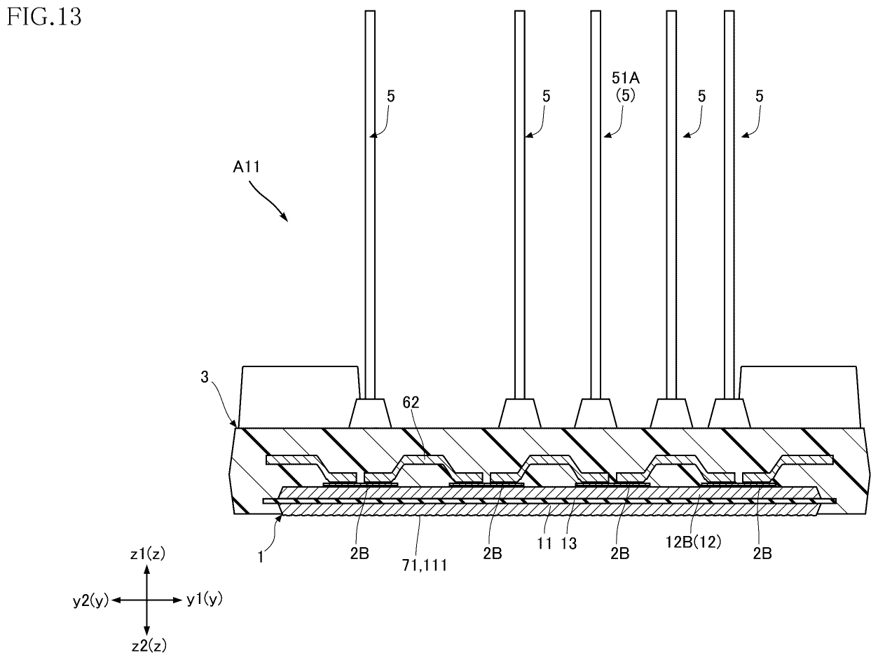

FIGS. 12 to 17 show a variation and another embodiment of the present disclosure. In these figures, elements that are identical or similar to those in the first embodiment are marked with the same reference numerals. Various configurations in the variation and the embodiment described below may be combined properly with each other to the extent that no technical contradictions arise.

### First Variation of First Embodiment:

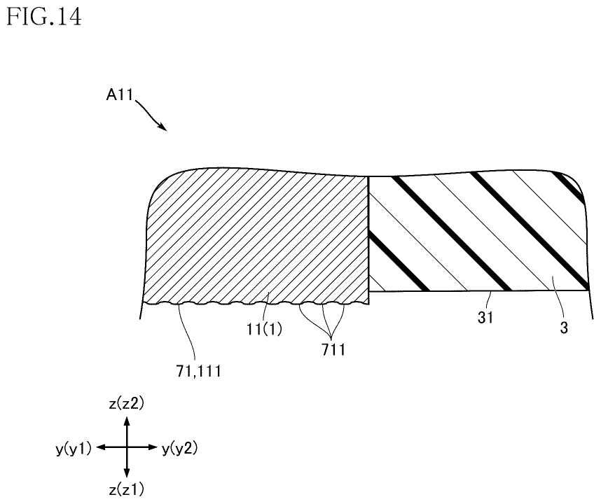

FIGS. 12 to 14 show a first variation of the semiconductor device A1. In the semiconductor device A11 of this variation, no second uneven region 72 is formed on the reverse surface 31 of the sealing member 3. As shown in FIG. 14, the reverse surface 31 is a flat, smooth surface, unlike the first uneven region 71 or the second uneven region 72 of the semiconductor device A1.

In the semiconductor device A11, as shown in FIG. 14, the first metal layer 11 includes a portion located on the z2 side in the thickness direction z with respect to the reverse surface 31. In other words, in the state before the above-mentioned mechanical cutting is performed, the first metal layer 11 protrudes beyond the reverse surface 31 of the sealing member 3 toward the z2 side in the thickness direction z. By performing mechanical cutting only on the first metal layer 11, a first uneven region 71 is formed on the first surface 111, while no second uneven region 72 is formed on the reverse surface 31.

This variation is also capable of suppressing insufficient heat dissipation. It is possible to press the first surface 111 firmly against the cooling system 9 shown in FIG. 9, which is advantageous for improving heat dissipation efficiency. As understood from this variation, the semiconductor device of the present disclosure may have a first uneven region 71 formed on the first surface 111, and a second uneven region 72 may not be formed on the reverse surface 31.

### Second Embodiment

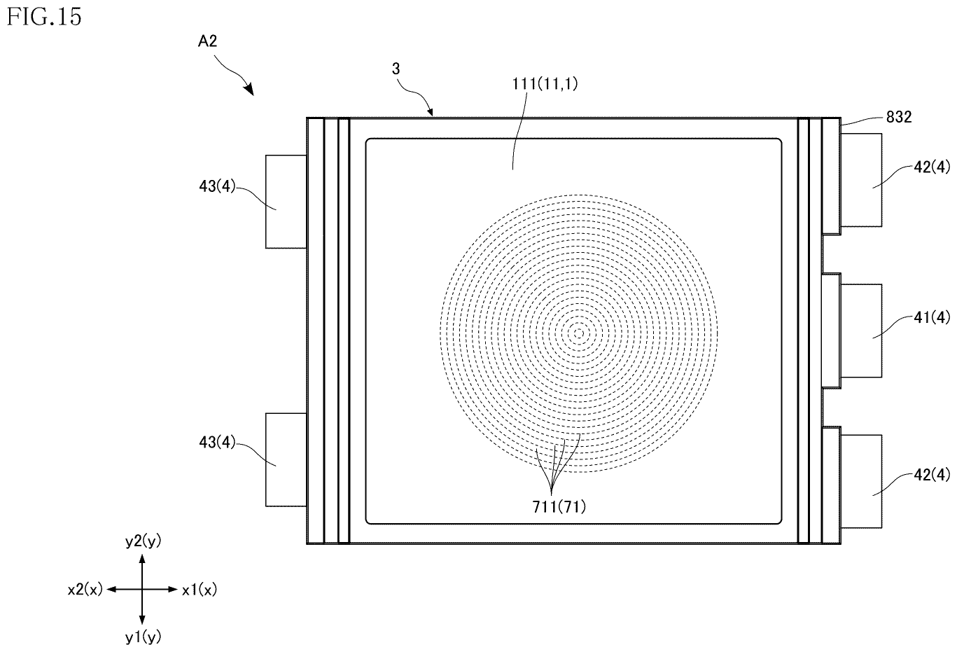

FIG. 15 shows a semiconductor device A2 according to a second embodiment of the present disclosure. The semiconductor device A2 may have a first uneven region 71 whose configuration differs from that of the above-discussed embodiment. In the second embodiment, the first uneven region 71 is formed only in a part of the first surface 111. Specifically, the first uneven region 71 is located in a limited region at and around the center of the first surface 111, as viewed in the thickness direction z. The first uneven region 71 is surrounded by the remaining region of the first surface 111, i.e., the region that is smoother than the first uneven region 71.

The method for forming the first uneven region 71 in the second embodiment is not limitative. For example, use may be made of laser processing to form the first uneven region 71.

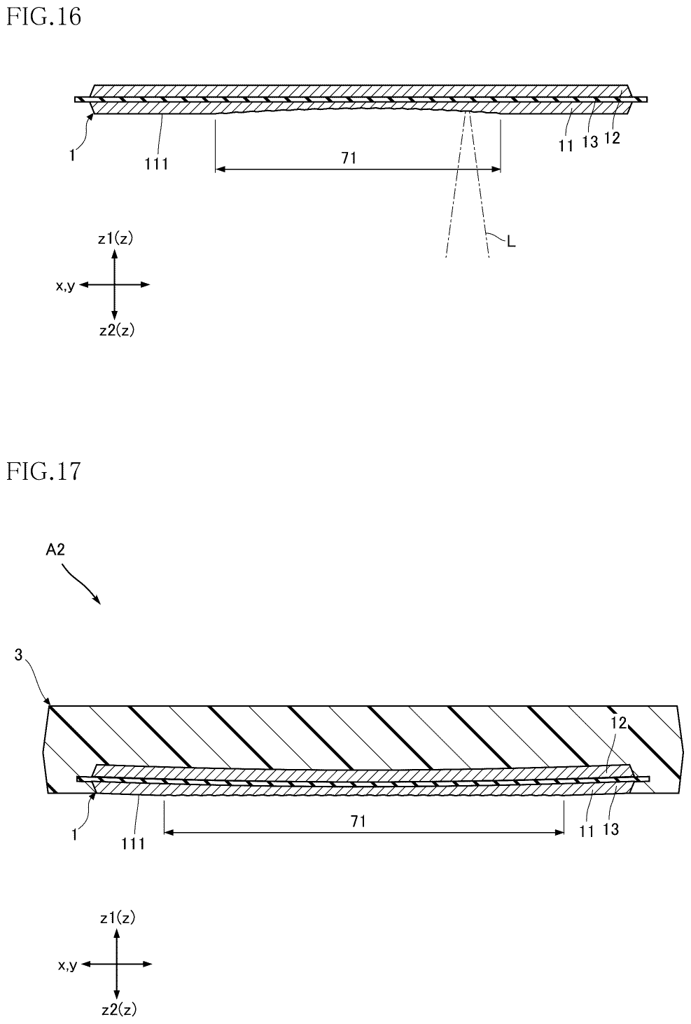

FIGS. 16 and 17 show steps of the manufacturing method of the semiconductor device A2. FIG. 16 shows the support member 1 before first semiconductor elements 2A and second semiconductor elements 2B are mounted. In this state, no significant warping occurs in the support member 1. However, as explained above with reference to FIGS. 10 and 11, the second embodiment may suffer, without any measures, the warping of the support member 1 toward the z2 side of the thickness direction z after the first semiconductor elements 2A and the second semiconductor elements 2B are mounted and the sealing member 3 is completed. In light of this, laser processing with laser light L may be performed on the area of the first surface 111 that is predicted to bulge toward the z2 side in the thickness direction z after the sealing member 3 is completed. By irradiating laser light L, it is possible to locally remove a desired part of the first metal layer 11. The type of laser light L and the irradiation conditions may be set properly in various ways. For example, a pulse laser or a green laser may be used. In the illustrated example, the laser light L is moved in a number of concentric circles with respect to the first surface 111. As a whole, the resulting first uneven region 71 may be concave as descending toward the z1 side in the thickness direction z. For instance, the output power and/or irradiation time of the laser light L may be set such that the depth of the first uneven region 71 in the thickness direction z becomes greater as proceeding from the periphery to the center.

FIG. 17 shows the state in which the sealing member 3 is completed after the first semiconductor elements 2A and the second semiconductor elements 2B are mounted. For ease of understanding, FIG. 17 shows only the support member 1 and the sealing member 3. In manufacturing the semiconductor device A2, the support member 1 tends to warp and bulge toward the z2 side in the thickness direction z. However, since the first uneven region 71 is initially concave as a whole toward the z1 side in the thickness direction z, the first uneven region 71 as a whole will not exhibit any significant concavity or bulging after the warping, except for the local irregularities due to the uneven lines 711 included in the first uneven region 71.

The embodiment above also suppresses insufficient heat dissipation. The first uneven region 71 may be formed over the entire first surface 111 or only on a part thereof. The method for forming the first uneven region 71 is not limitative, and any method capable of forming the uneven lines 711 in the first uneven region 71 is usable. The first uneven region 71 may be formed before or after the sealing member 3 is formed.

The semiconductor device and the method for manufacturing the semiconductor device of the present disclosure are not limited to the above embodiments/variations. The specific configurations of the semiconductor device and the manufacturing method thereof may be modified in various ways. The present disclosure includes the embodiments described below in the following clauses.

### Clause 1.

A semiconductor device comprising:
a support member;
a semiconductor element disposed on a first side in a thickness direction relative to the support member; and
a sealing member covering a part of the support member and the semiconductor element,
wherein the support member has a first surface facing a second side in the thickness direction and exposed from the sealing member, and the first surface is formed with a first uneven region.

### Clause 2.

The semiconductor device according to clause 1, wherein the first uneven region has an arithmetic mean roughness of not less than 0.2 μm and not greater than 13 μm.

### Clause 3.

The semiconductor device according to clause 1 or 2, wherein the first uneven region includes a plurality of uneven lines in an arc shape.

### Clause 4.

The semiconductor device according to any one of clauses 1 to 3, wherein an entirety of the first surface is provided with the first uneven region.

### Clause 5.

The semiconductor device according to any one of clauses 1 to 3, wherein a part of the first surface is provided with the first uneven region.

### Clause 6.

The semiconductor device according to any one of clauses 1 to 5, wherein the support member includes a first metal layer forming the first surface.

### Clause 7.

The semiconductor device according to any one of clauses 1 to 6, wherein the sealing member has a resin reverse surface,
the first surface is exposed from the resin reverse surface.

### Clause 8.

The semiconductor device according to clause 7, wherein the resin reverse surface is provided with a second uneven region.

### Clause 9.

The semiconductor device according to clause 8, wherein a plurality of uneven lines of the first uneven region and a plurality of uneven lines of the second uneven region are continuous with each other.

### Clause 10.

The semiconductor device according to clause 7, wherein the resin reverse surface is a flat surface.

### Clause 11.

The semiconductor device according to any one of clauses 1 to 10, wherein a main component of the first metal layer is Cu.

### Clause 12.

The semiconductor device according to clause 11, wherein the support member includes an insulating layer disposed on the first side in the thickness direction relative to the first metal layer.

### Clause 13.

The semiconductor device according to clause 12, wherein the support member includes a second metal layer disposed on the first side in the thickness direction relative to the insulating layer.

### Clause 14.

The semiconductor device according to clause 13, wherein the semiconductor element is mounted on the second metal layer.

### Clause 15.

The semiconductor device according to clause 14, wherein a plurality of semiconductor elements are provided,
the second metal layer includes a first region and a second region spaced apart from each other in a direction perpendicular to the thickness direction,
the plurality of semiconductor elements include a first semiconductor element mounted on the first region and a second semiconductor element mounted on the second region.

### Clause 16.

The semiconductor device according to clause 15, wherein the first semiconductor element and the second semiconductor element are switching elements.

### Clause 17.

A vehicle comprising:
a drive source; and
the semiconductor device in accordance with any one of clauses 1 to 16,
wherein the semiconductor device is electrically connected to the drive source.

### Clause 18.

A method for manufacturing a semiconductor device that comprises:
a support member;
a semiconductor element disposed on a first side in a thickness direction relative to the support member; and
a sealing member covering a part of the support member and the semiconductor element,
wherein the support member includes a first surface facing a second side in the thickness direction and exposed from the sealing member,
the method comprising:
providing the first surface with an uneven region by subjecting the first surface to machine cutting.

### REFERENCE NUMERALS

A1, A22, A2: Semiconductor device B: Vehicle 1; Support member 2A; First semiconductor element 2B: Second semiconductor element 3: Sealing member 4: Main current terminal 5: Control terminal 9: Cooling system 11: First metal layer 12: Second metal layer 12A: First region 12B: Second region 13: Insulating layer 20A: Upper arm circuit 20B: Lower arm circuit 31: Reverse surface 41: First power terminal 42: Second power terminal 43: Output terminal 51A: First gate terminal 51B: Second gate terminal 61: First conductive member 62: Second conductive member 71: First uneven region 72: Second uneven region 81: On-board charger 82: Storage battery 83: Drive train 91: Heat transfer medium 111: First surface 711: Uneven line 721: Uneven line 831: Inverter 832: Drive source Ct: Cutting tool L: Lase light x: First direction y: Second direction z: Thickness direction

1. A semiconductor device comprising:
a support member;
a semiconductor element disposed on a first side in a thickness direction relative to the support member; and
a sealing member covering a part of the support member and the semiconductor element,
wherein the support member has a first surface facing a second side in the thickness direction and exposed from the sealing member, and
the first surface is formed with a first uneven region.

2. The semiconductor device according to claim 1, wherein the first uneven region has an arithmetic mean roughness of not less than 0.2 μm and not greater than 13 μm.

3. The semiconductor device according to claim 1, wherein the first uneven region includes a plurality of uneven lines in an arc shape.

4. The semiconductor device according to claim 1, wherein an entirety of the first surface is provided with the first uneven region.

5. The semiconductor device according to claim 1, wherein a part of the first surface is provided with the first uneven region.

6. The semiconductor device according to claim 1, wherein the support member includes a first metal layer forming the first surface.

7. The semiconductor device according to claim 1, wherein the sealing member has a resin reverse surface,
the first surface is exposed from the resin reverse surface.

8. The semiconductor device according to claim 7, wherein the resin reverse surface is provided with a second uneven region.

9. The semiconductor device according to claim 8, wherein a plurality of uneven lines of the first uneven region and a plurality of uneven lines of the second uneven region are continuous with each other.

10. The semiconductor device according to claim 7, wherein the resin reverse surface is a flat surface.

11. The semiconductor device according to claim 1, wherein a main component of the first metal layer is Cu.

12. The semiconductor device according to claim 11, wherein the support member includes an insulating layer disposed on the first side in the thickness direction relative to the first metal layer.

13. The semiconductor device according to claim 12, wherein the support member includes a second metal layer disposed on the first side in the thickness direction relative to the insulating layer.

14. The semiconductor device according to claim 13, wherein the semiconductor element is mounted on the second metal layer.

15. The semiconductor device according to claim 14, wherein a plurality of semiconductor elements are provided,
the second metal layer includes a first region and a second region spaced apart from each other in a direction perpendicular to the thickness direction,
the plurality of semiconductor elements include a first semiconductor element mounted on the first region and a second semiconductor element mounted on the second region.

16. The semiconductor device according to claim 15, wherein the first semiconductor element and the second semiconductor element are switching elements.

17. A vehicle comprising:
a drive source; and
the semiconductor device in accordance with claim 1,
wherein the semiconductor device is electrically connected to the drive source.

18. A method for manufacturing a semiconductor device that comprises:
a support member;
a semiconductor element disposed on a first side in a thickness direction relative to the support member, and
a sealing member covering a part of the support member and the semiconductor element,
wherein the support member includes a first surface facing a second side in the thickness direction and exposed from the sealing member,
the method comprising:
providing the first surface with an uneven region by subjecting the first surface to machine cutting.
